(19) United States
(12) Patent Application Publication
(10) Pub. No.: US 2018/0219031 A1
(43) Pub. Date: Aug. 2, 2018

(54) FAN-OUT STRUCTURE AND ELECTRONIC DEVICE

(71) Applicant: Shenzhen China Star Optoelectronics Technology Co. Ltd., Shenzhen (CN)

(72) Inventor: Peng DU, Shenzhen (CN)

(73) Assignee: Shenzhen China Star Optoelectronics Technology Co. Ltd., Shenzhen (CN)

(21) Appl. No.: 14/897,763

(22) PCT Filed: Oct. 28, 2015
(86) PCT No.: PCT/CN2015/093011

§ 371 Date: Feb. 13, 2018

(30) Foreign Application Priority Data
Sep. 25, 2015 (CN) 201510623375.8

(51) Int. Cl. H01L 27/12; G02F 1/1345; G02F 1/1362

(52) U.S. Cl. CPC H01L 27/1255; G02F 1/1345; G02F 1/1368; H01L 27/124; G02F 1/136286

(57) ABSTRACT

Provided is a fan-out structure and an electronic device. In the fan-out structure, first fan-out lines are located on a different metal layer from second fan-out lines, and vertical projections of the first fan-out lines on the second metal layer partially overlap with the second fan-out lines, so as to form capacitance between the first fan-out lines and the second fan-out lines. The display effects of a display panel can be remarkably improved while a frame of the electronic device is favorably narrowed.

### CROSS-REFERENCE TO RELATED APPLICATIONS

The present application claims the priority of Chinese patent application CN 201510623375.8, entitled “Fan-out structure and electronic device” and filed on Sep. 25, 2015, the entirety of which is incorporated herein by reference.

### FIELD OF THE INVENTION

The present disclosure relates to the field of display technologies, and in particular, to a fan-out structure. The present disclosure further relates to an electronic device with the fan-out structure.

### BACKGROUND OF THE INVENTION

A liquid crystal display panel, as an important component of a liquid crystal display device, can display an image under the cooperation of a backlight module and driven by a driving circuit.

Generally, a Thin Film Transistor (TFT) array area is provided on an array substrate of the liquid crystal display panel. The TFT array area is filled with signal lines and TFTs. A driving circuit board connects the signal lines of the array substrate with solder pins of the driving circuit board, through a fan-out structure having a plurality of fan-out lines. In general, the fan-out lines have inhomogeneously distributed resistances due to close arrangement of the solder pins and dispersed arrangement of the signal lines (i.e., the distances from the solder pins to the signal lines are different from each other). The fan-out lines of different lengths have different resistances, which causes deformation of a signal waveform, thereby deteriorating the display quality of the liquid crystal display device.

In order to solve the problem of inhomogeneous distribution of resistances of the fan-out lines, the lengths of the fan-out lines are adjusted based on the positions of the fan-out lines in the prior art, so that the resistance for each of the fan-out lines of the fan-out structure can be matched. In the following, the fan-out structure as shown in FIG. 1 will be used as an example to illustrate a procedure of resistance matching. All fan-out lines 11′ of the fan-out structure shown in FIG. 1 are located in a same metal layer, and any adjacent two fan-out lines 11′ do not overlap with each other. In order to enable all the fan-out lines 11′ to have a same resistance, the fan-out lines 11′ closer to both ends have smaller bends, while the fan-out lines 11′ closer to a middle part have more bends.

However, in the prior art, while the fan-out structure is being designed, only the influence of inhomogeneous distribution of resistance on the display effect is considered, whereas the influence of inhomogeneously distributed capacitance on the display effect has been left out of consideration. In fact, as an RC signal delay of the signal line is caused by co-action of resistance and capacitance, the display effect of the display panel will be affected as well in case only the distribution of the resistance is considered, while that of the capacitance is not taken into account. In addition, as shown in FIG. 1, non-overlapped arrangement of the fan-out lines 11′ will result in an increase in the overall height of the fan-out structure, which is unfavorable for narrowing a frame of the liquid crystal display panel.

### SUMMARY OF THE INVENTION

The technical problems to be solved in the present disclosure include: when a fan-out structure is being designed at present, only the influence of inhomogeneous distribution of resistance on the display effect is taken into account, and the influence of inhomogeneous distribution of capacitance on the display effect is left out of consideration; and lack of an overlapping region between fan-out lines of the fan-out structure in the prior art results in an increase in the overall height of the fan-out structure, which is unfavorable for narrowing a frame of a liquid crystal display panel.

In order to solve the above technical problems, a fan-out structure is provided in the present disclosure.

According to an aspect of the present disclosure, a fan-out structure is provided, comprising:

a plurality of first fan-out lines provided on a first metal layer; and

a plurality of second fan-out lines provided on a second metal layer, an insulating layer being disposed between the second metal layer and the first metal layer,

wherein vertical projections of the first fan-out lines on the second metal layer are alternately arranged with the second fan-out lines, and the vertical projections partially overlap with adjacent second fan-out lines.

Preferably, each of the first fan-out lines and the second fan-out lines has a fan-out portion and a regulating portion connected to each other, the fan-out portion being straight wiring, and the regulating portion being curved wiring in a reciprocating manner, and

a vertical projection of the regulating portion of the first fan-out line on the second metal layer partially overlaps with the regulating portion of the second fan-out line.

Preferably, the regulating portion has a bending angle of 90°.

Preferably, the insulating layer is formed on the first metal layer, and the second metal layer is formed on the insulating layer; or

the insulating layer is formed on the second metal layer, and the first metal layer is formed on the insulating layer.

Preferably, the first fan-out lines and the second fan-out lines are made of a same material.

According to another aspect of the present disclosure, an electronic device is provided, comprising:

a substrate; and

a fan-out structure provided on the substrate, wherein the fan-out structure includes:
a plurality of first fan-out lines provided on a first metal layer; and
a plurality of second fan-out lines provided on a second metal layer, an insulating layer being disposed between the second metal layer and the first metal layer,
wherein vertical projections of the first fan-out lines on the second metal layer are alternately arranged with the second fan-out lines, and the vertical projections partially overlapping with adjacent second fan-out lines.

Preferably, each of the first fan-out lines and the second fan-out lines has a fan-out portion and a regulating portion connected to each other, the fan-out portion being straight wiring, and the regulating portion being curved wiring in a reciprocating manner with a bending angle of 90°; and

a vertical projection of the regulating portion of each first fan-out line on the second metal layer partially overlaps with the regulating portion of a corresponding second fan-out line.

Preferably, the insulating layer is formed on the first metal layer, and the second metal layer is formed on the insulating layer; or

the insulating layer is formed on the second metal layer, and the first metal layer is formed on the insulating layer.

Preferably, the first fan-out lines and the second fan-out lines are made of a same material.

Preferably, the electronic device is a liquid crystal display panel.

Compared with the prior art, one or more embodiments of the solution described above may have the following advantages or benefits.

In the fan-out structure of the present disclosure, the first fan-out lines and the second fan-out lines are located on different metal layers respectively, and the vertical projections of the first fan-out lines on the second metal layer partially overlap with the second fan-out lines, such that capacitance forms between the fan-out lines and the second fan-out lines. On the basis of the present disclosure, those skilled in the art can, through adjustment of sizes of the overlapping regions, compensate for differences in resistances of the fan-out lines with the capacitance formed, so as to render the time constants of all the fan-out lines approximately or exactly equal to each other. That is, such an arrangement enables all the fan-out lines to have a same signal delay, thereby improving the display effect of the liquid crystal display panel. In addition, compared with an existing solution of non-overlapped fan-out lines, in the solution of the embodiment of the present disclosure, the vertical projections of the first fan-out lines partially overlap with the second fan-out lines, thereby effectively reducing the overall height of the fan-out structure. This is favorable for narrowing the frame of electronic device having the fan-out structure.

Other features and advantages of the present disclosure will be further explained in the following description, and partly become self-evident therefrom, or be understood through implementation of the present disclosure. The objectives and other advantages of the present disclosure will be achieved through the structure specifically pointed out in the description, claims, and the accompanying drawings.

### BRIEF DESCRIPTION OF THE DRAWINGS

The drawings are provided for further understanding of the present disclosure, and constitute one part of the description. They serve to explain the present disclosure in conjunction with the embodiments, rather than to limit the present disclosure in any manner. In the drawings:

FIG. 1 schematically shows the structure of a fan-out structure in the prior art;

FIG. 2 schematically shows a cross-section view of a fan-out structure according to an embodiment of the present disclosure;

FIG. 3 shows a top view of the fan-out structure according to the embodiment of the present disclosure, wherein a heavy solid line represents a projection of a first metal line on a second metal layer, and a light solid line represents a second metal line;

FIG. 4 schematically shows a contour of the fan-out structure as shown in FIG. 3 in a top view; and

FIG. 5 schematically shows dimensions of the fan-out structure as shown in FIG. 3.

### DETAILED DESCRIPTION OF THE EMBODIMENTS

The present disclosure will be explained in detail with reference to the embodiments and the accompanying drawings in the following, whereby it can be fully understood how to solve the technical problem by the technical means according to the present disclosure and achieve the technical effects thereof, and thus the technical solution according to the present disclosure can be implemented. It is important to note that as long as there is no structural conflict, all the technical features mentioned in all the embodiments may be combined together in any manner, and the technical solutions obtained therefrom all fall within the scope of the present disclosure.

The technical problems to be solved in the present disclosure include: in the design of a fan-out structure at present, only the influence of inhomogeneous distribution of resistance on the display effect is taken into account, and the influence of inhomogeneous distribution of capacitance on the display effect is left out of consideration; and lack of an overlapping region between fan-out lines of the fan-out structure in the prior art results in an increase in the overall height of the fan-out structure, which is unfavorable for narrowing a frame of a liquid crystal display panel. In order to solve the above technical problems, a fan-out structure is provided in an embodiment of the present disclosure.

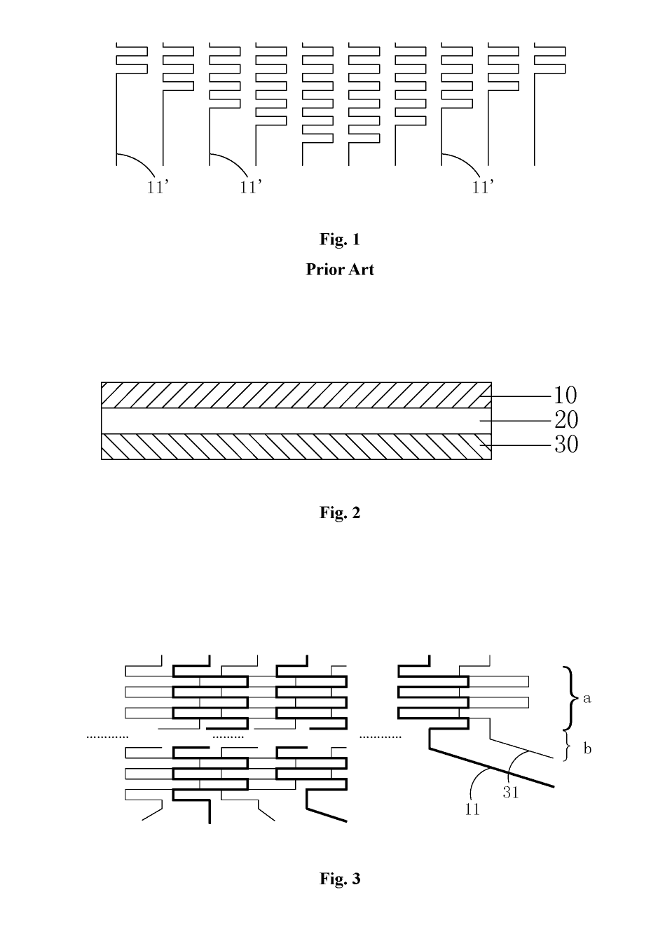

FIG. 2 schematically shows a cross-section view of a fan-out structure according to the embodiment of the present disclosure. FIG. 3 shows a top view of the fan-out structure according to the embodiment of the present disclosure, wherein heavy solid lines represent projections 11 of first metal lines on a second metal layer 30, and light solid lines represent second metal lines 31. As indicated in FIGS. 2 and 3, the fan-out structure of the embodiment of the present disclosure mainly includes a plurality of first fan-out lines (only the vertical projections 11 corresponding to the first fan-out lines are shown in the drawing) and a plurality of second fan-out lines 31.

Specifically, the first fan-out lines and the second fan-out lines 31 are provided in different layers. In the present embodiment, all the first fan-out lines are provided on a first metal layer 10, and all the second fan-out lines 31 are provided on the second metal layer 30. An insulating layer 20 is disposed between the first metal layer 10 and the second metal layer 30. Herein, the first metal layer 10 may be located below the second metal layer 30. That is, the insulating layer 20 is formed on the first metal layer 10, and the second metal layer 30 is formed on the insulating layer 20. The first metal layer 10 may also be located above the second metal layer 30. That is, the insulating layer 20 is formed on the second metal layer 30, and the first metal layer 10 is formed on the insulating layer 20.

The heavy solid lines shown in FIG. 3 represent the vertical projections 11 of the first fan-out lines on the second metal layer 30. The vertical projections 11 of the first fan-out lines on the second metal layer 30 and the second fan-out lines 31 are alternately arranged. That is, except the first fan-out lines located at edges, a left side and a right side of the vertical projection 11 of each of the remaining first fan-out lines are respectively provided with the second fan-out lines 31. The vertical projection 11 of a first fan-out line partially overlaps with adjacent second fan-out lines 31, so as to form capacitance between the first fan-out line and the second fan-out lines 31.

According to the fan-out structure of this embodiment, the first fan-out lines and the second fan-out lines 31 are located on different metal layers, respectively, and the vertical projections 11 of the first fan-out lines on the second metal layer 30 partially overlap with the second fan-out lines 31, such that capacitance is formed between the first fan-out lines and the second fan-out lines 31. On the basis of the present embodiment, those skilled in the art can, through adjustment of sizes of overlapping regions, compensate for differences in resistances of the fan-out lines with the capacitance as formed, so as to render time constants of all the fan-out lines in the fan-out structure approximately or exactly equal to each other. That is, such an arrangement enables all the fan-out lines to have a same signal delay, thereby improving the display effect of the liquid crystal display panel. In addition, compared with an existing solution of non-overlapped fan-out lines, in the solution of this embodiment, the vertical projections 11 of the first fan-out lines partially overlap with the second fan-out lines 31, thereby effectively reducing the overall height of the fan-out structure. This is favorable for narrowing the frame of an electronic device having the fan-out structure.

In a preferred embodiment of the present disclosure, the first fan-out line and the second fan-out line 31 have a same structure. The first fan-out line, for example, includes a fan-out portion b and a regulating portion a, which are connected to each other. The fan-out portion b is straight wiring, and the regulating portion a is curved wiring in a reciprocating manner. The vertical projection 11 of the first fan-out line and the second fan-out line 31 overlap in the regulating portion a. That is, a vertical projection of the regulating portion a of the first fan-out line on the second metal layer 30 partially overlap with the regulating portion a of the second fan-out line 31.

In particular, in order to facilitate the calculation of the time constants of the fan-out lines, a bending angle of the regulating portion a can be preferably adjusted to be 90°. The first fan-out lines 11 and the second fan-out lines 31 are made of a same material, which can be copper or aluminum.

In a specific implementing step, a size of an overlapping region between each fan-out line and adjacent fan-out lines can be calculated based on the principle that all the fan-out lines in the fan-out structure correspond to an equal time constant.

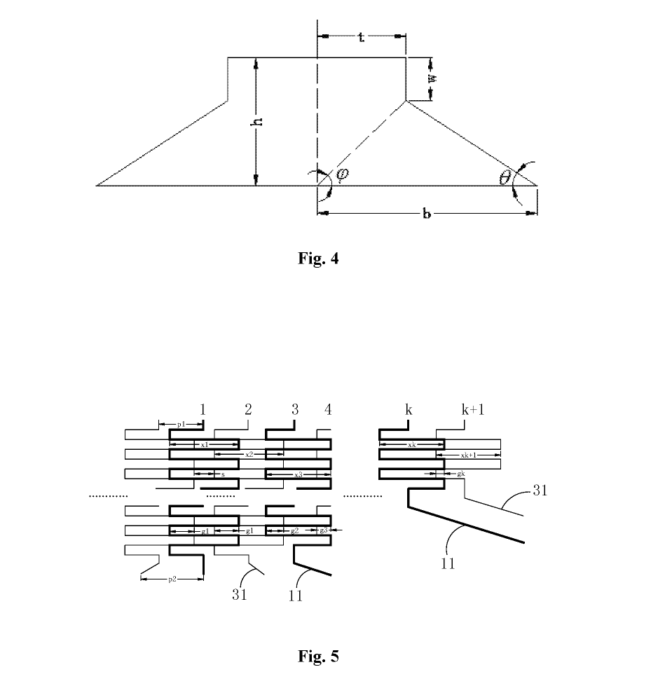

The step of calculating the size of the overlapping region of each of the fan-out lines and its adjacent fan-out lines in specific implementation will be described in detail with reference to FIGS. 4 and 5. In order to facilitate the calculation, the fan-out structure is optimized as follows: (1) the first fan-out lines and the second fan-out lines 31 of the fan-out structure are made of the same material, a sheet resistance of which is assumed to be Rs; (2) the regulating portions a of the fan-out lines are arranged in upper portions of the fan-out structure, and the fan-out portions b of the fan-out lines are arranged in lower portions of the fan-out structure; (3) all the regulating portions a are parallel to each other; (4) the bending angle of the regulating portions a is 90°; (5) the regulating portion a of each of the fan-out lines have equally wide upper edge and lower edge, and all the regulating portions a have an equal width (assumed to be w); (6) all bending portions of the regulating portions a are of equal height (assumed to bey); and (7) the fan-out lines overlap with one another only at the regulating portions a.

In FIG. 4, h, t, and b denote height of the fan-out line, half of an upper width of the fan-out structure, and half of a lower width of the fan-out structure, respectively, and w represents length of the regulating portion a of an outermost fan-out line. φ represents an angle formed between a lower end surface of the fan-out structure and a line connecting a lower end of the regulating portion a of the fan-out line and a center of the lower end surface of the fan-out structure. θ denotes an angle formed between the fan-out portion of the outermost fan-out line and the lower end surface of the fan-out structure. These two angles are used subsequently for accurate calculation of resistances and capacitances of the fan-out lines.

As shown in FIG. 5, the alternately arranged vertical projections 11 of the first fan-out lines and the second fan-out lines 31 are sequentially numbered. The vertical projection 11 of the first fan-out line located in a middle is numbered 1. With the vertical projection 11 of this first fan-out line as a center, the numbers are sequentially increased toward both sides thereof. FIG. 5 shows only the numbers of the second fan-out lines 31 and the vertical projections 11 of the first fan-out lines located on a right side of the vertical projection 11 of the first fan-out line located in the middle.

The time constant of the first fan-out line numbered 1 is first calculated.

In FIG. 5, p1 indicates a distance between the vertical projection 11 of the first fan-out line numbered 1 and an upper pin pitch of the second fan-out line 31 of a previous number; p2 indicates a distance between the vertical projection 11 of the first fan-out line numbered 1 and a lower pin pitch of the second fan-out line 31 of the previous number; x1 represents the width of the vertical projection of the regulating portion a of the first fan-out line numbered 1; s represents a minimum distance among the vertical projections 11 of all the first fan-out lines or among all the second fan-out lines 31; and g1 represents the width of an overlapping region between the vertical projection 11 of the first fan-out line numbered 1 and two adjacent second fan-out lines 31 thereof. As can be seen from FIG. 5, g1=p1−s, and x1=2g1+s=2p1−s.

Regarding two angles θ and φ marked in FIG. 4, they satisfy the following relationships:

$$tan θ = \frac{h - w}{n ( p 2 - p 1 )} , and tan ϕ = \frac{h - w}{n \cdot p 1} .$$

The vertical projection 11 of the first fan-out line numbered 1 has a length

$$L 1 = h + \frac{h}{y} \cdot x 1 = h + \frac{h}{y} \cdot ( 2 p 1 - s ) ,$$

and a resistance

$$R 1 = R s \cdot \frac{L 1}{w} = \frac{R s \cdot [ h + \frac{h}{y} \cdot ( 2 p 1 - s ) ]}{w} .$$

The overlapping region between the vertical projection 11 of the first fan-out line numbered 1 and the adjacent two second fan-out lines 31 has an area

$$\\ A 1 = 2 \frac{h}{y} \cdot ( p 1 - s ) .$$

The first fan-out lines and the second fan-out lines 31 both have an absolute dielectric constant of ε₀, and the insulating layer 20 has a relative dielectric constant of εᵣ, and a thickness of tᵢₙₛ. Thus, the capacitance of the first fan-out line numbered 1 can be calculated:

$$C 1 = \frac{{ɛ}_{0} \cdot {ɛ}_{r} \cdot A 1}{{t}_{ins}} = \frac{2 {ɛ}_{0} \cdot {ɛ}_{r} \cdot h \cdot ( p 1 - s )}{y \cdot {t}_{ins}} .$$

Finally, the time constant of the first fan-out line numbered 1 can be obtained:

$$τ 1 = R 1 \cdot C 1 = \frac{Rs \cdot [ h + \frac{h}{y} \cdot ( 2 p 1 - s ) ]}{w} \cdot \frac{2 {ɛ}_{0} \cdot {ɛ}_{r} \cdot h \cdot ( p 1 - s )}{y \cdot {t}_{ins}} . \qquad ( 1 )$$

Next, a similar procedure can be performed on the second fan-out line 31 numbered 2, to obtain the width of the regulating portion a of the second fan-out line 31 numbered 2: x2=2g1+s=2p1−s. The second fan-out line 31 numbered 2 has a total length:

$$L 2 = ( h - p 1 \cdot tan ϕ ) ( 1 + \frac{x 2}{y} ) + \frac{p 1 \cdot tan ϕ}{sin θ} = ( h - p 1 \cdot tan ϕ ) ( 1 + \frac{2 p 1 - s}{y} ) + \frac{p 1 \cdot tan ϕ}{sin θ} ,$$

and a resistance:

$$R 2 = Rs \cdot \frac{L 2}{w} = Rs \cdot \frac{( h - p 1 \cdot tan ϕ ) ( 1 + \frac{2 p 1 - s}{y} ) + \frac{p 1 \cdot tan ϕ}{sin θ}}{w} .$$

g2, in representation of the width of an overlapping region between the second fan-out line 31 numbered 2 and the vertical projection 11 of the first fan-out line numbered 3, determines, together with g1, capacitance of the second fan-out line 31 numbered 2. An overlapping region among the second fan-out line 31 numbered 2, the vertical projection 11 of the first fan-out line numbered 1, and the vertical projection 11 of the first fan-out line numbered 3 has an area and a capacitance respectively as:

$$A 2 = \frac{h - p 1 \cdot tan ϕ}{y} ( g 1 + g 2 ) , and$$

$$C 2 = \frac{{ɛ}_{0} \cdot {ɛ}_{r} \cdot A 2}{{t}_{ins}} .$$

Finally, the time constant of the second fan-out line 31 numbered 2 can be obtained:

$$τ 2 = R 2 \cdot C 2 = R s \cdot \frac{( h - p 1 \cdot tan ϕ ) ( 1 + \frac{x 2}{y} ) + \frac{p 1 \cdot tan ϕ}{sin θ}}{w} \cdot \frac{{ɛ}_{0} \cdot {ɛ}_{r} \cdot A 2}{{t}_{ins}} . \qquad ( 2 )$$

The time constant of the first fan-out line numbered 1 is equal to the time constant of the second fan-out line 31 numbered 2, i.e., τ2=τ1. Thus:

R2·C2=R1·C1 (3)

Equations (1), (2), and (3) can be combined to calculate the value of the unknown parameter g2:

$$2 L 1 \cdot h \cdot g 1 = L 2 \cdot ( h - g 1 \cdot tan ϕ ) ( g 1 + g 2 ) ⇒ g 2 = \frac{2 \cdot L 1 \cdot h \cdot g 1}{L 2 \cdot ( h - p 1 \cdot tan ϕ )} - g 1.$$

Similarly, for the first fan-out line numbered 3, the width of the regulating portion a thereof is x3=p1+g2. It is further possible to calculate its total length:

$$L 3 = ( h - 2 p 1 \cdot tan ϕ ) [ 1 + \frac{1}{y} \cdot ( p 1 + g 2 ) ] + \frac{2 p 1 \cdot tan ϕ}{sin θ} .$$

Thus, the resistance of the first fan-out line numbered 3 is:

$$R 3 = Rs \cdot \frac{L 3}{w} = R s \cdot \frac{( h - 2 p 1 \cdot tan ϕ ) [ 1 + \frac{1}{y} \cdot ( p 1 + g 2 ) ] + \frac{2 p 1 \cdot tan ϕ}{sin θ}}{w} .$$

g3, in representation of the width of an overlapping region between the vertical projection 11 of the first fan-out line numbered 3 and the second fan-out line 31 numbered 4, determines, together with g2, capacitance of the first fan-out line numbered 3. An overlapping region among the vertical projection 11 of the first fan-out line numbered 3, the second fan-out line 31 numbered 2, and the second fan-out line 31 numbered 4 has an area and capacitance respectively as:

$$A 3 = \frac{( h - 2 p 1 \cdot tan ϕ )}{y} \cdot ( g 2 + g 3 ) , and$$

$$C 3 = \frac{{ɛ}_{0} \cdot {ɛ}_{r} \cdot A 3}{{t}_{ins}} .$$

Finally, the time constant of the first fan-out line 31 numbered 3 can be obtained:

$$τ 3 = R 3 \cdot C 3 = Rs \cdot \frac{( h - 2 p 1 \cdot tan ϕ ) [ 1 + \frac{1}{y} \cdot ( p 1 + g 2 ) ] + \frac{2 p 1 \cdot tan ϕ}{sin θ}}{w} \cdot \frac{{ɛ}_{0} \cdot {ɛ}_{r} \cdot A 3}{{t}_{ins}} . \qquad ( 4 )$$

The time constant of the second fan-out line 31 numbered 2 is equal to the time constant of the first fan-out line numbered 3, i.e., τ3=τ2. Thus:

R3·C3=R2·C2 (5)

Equations (1) to (5) can be combined to calculate the value of the unknown parameter g3:

$$L 3 \cdot ( h - 2 p 1 \cdot tan ϕ ) ( g 2 + g 3 ) = L 2 \cdot ( h - p 1 \cdot tan ϕ ) ( g 1 + g 2 ) ⇒ g 3 = \frac{L 2 \cdot ( h - p 1 + tan ϕ ) ( g 1 + g 2 )}{L 3 \cdot ( h - 2 p 1 \cdot tan ϕ )} - g 2.$$

A similar conclusion can be drawn for any wire satisfying k≥3, and the regulating portion a of a k^{th} fan-out line has a width: x(k)=p1+g(k−1), wherein, g(k−1) is the width of an overlapping region between a (k−1)^{th} fan-out line and the k^{th} fan-out line. Thus, a total length of the k^{th} fan-out line is:

$$L ( k ) = [ h - ( k - 1 ) \cdot tan ϕ ] [ 1 + \frac{1}{y} \cdot x ( k ) ] + \frac{( k - 1 ) p 1 \cdot tan ϕ}{sin θ} .$$

A total resistance of the k^{th} fan-out line is:

$$R ( k ) = Rs \cdot \frac{L ( k )}{w} ,$$

wherein g(k) represents the width of an overlapping region between the fan-out line numbered k and the fan-out line numbered k+1, and determines, together with g(k−1), the capacitance of the fan-out line numbered k. The overlapping region between the k^{th} fan-out line and adjacent fan-out lines has an area and capacitance respectively as:

$$A ( k ) = \frac{h - ( k - 1 ) p 1 \cdot tan ϕ}{y} [ g ( k - 1 ) + g ( k ) ] , and$$

$$C ( k ) = \frac{{ɛ}_{0} \cdot {ɛ}_{r} \cdot A ( k )}{{t}_{ins}} .$$

Let the time constant τ(k) of the k^{th} fan-out line be equal to the time constant τ(k−1) of the (k−1)^{th} fan-out line, i.e., τ(k)=τ(k−1). The value of the unknown parameter g(k) can be calculated by recursive algorithm, i.e.:

$$g ( k ) = \frac{L ( k - 1 ) \cdot [ h - ( k - 2 ) \cdot p 1 \cdot tan ϕ ] [ g ( k - 2 ) + g ( k - 1 ) ]}{L ( k ) \cdot [ h - ( k - 1 ) p 1 \cdot tan ϕ ]} - g ( k - 1 ) .$$

Therefore, according to the above algorithm, an overlapping width corresponding to each of the fan-out lines can be determined, so as to achieve an equal impedance design among the fan-out lines.

Correspondingly, the present disclosure further provides an electronic device in an embodiment thereof. The electronic device according to the embodiment mainly includes a substrate and a fan-out structure as described in the above embodiment. The fan-out structure is provided on the substrate. The electronic device of the embodiment is preferably a liquid crystal display panel, which can be used in mobile phones, digital cameras, PDA and other electronic products.

The above embodiments are described only for better understanding, rather than restricting, the present disclosure. Any person skilled in the art can make amendments to the implementing forms or details without departing from the spirit and scope of the present disclosure. The scope of the present disclosure should still be subject to the scope defined in the claims.

1. A fan-out structure, comprising:
a plurality of first fan-out lines provided on a first metal layer; and
a plurality of second fan-out lines provided on a second metal layer, an insulating layer being disposed between the second metal layer and the first metal layer,
wherein vertical projections of the first fan-out lines on the second metal layer are alternately arranged with the second fan-out lines, and the vertical projections partially overlap with adjacent second fan-out lines.

2. The fan-out structure according to claim 1, wherein:
the insulating layer is formed on the first metal layer, and the second metal layer is formed on the insulating layer; or
the insulating layer is formed on the second metal layer, and the first metal layer is formed on the insulating layer.

3. The fan-out structure according to claim 1, wherein the first fan-out lines and the second fan-out lines are made of a same material.

4. The fan-out structure according to claim 1, wherein each of the first fan-out lines and the second fan-out lines has a fan-out portion and a regulating portion connected to each other, the fan-out portion being straight wiring, and the regulating portion being curved wiring arranged in a reciprocating manner; and
wherein a vertical projection of the regulating portion of each first fan-out line on the second metal layer partially overlaps with the regulating portion of a corresponding second fan-out line.

5. The fan-out structure according to claim 4, wherein:
the insulating layer is formed on the first metal layer, and the second metal layer is formed on the insulating layer; or
the insulating layer is formed on the second metal layer, and the first metal layer is formed on the insulating layer.

6. The fan-out structure according to claim 4, wherein the first fan-out lines and the second fan-out lines are made of a same material.

7. The fan-out structure according to claim 4, wherein the regulating portion has a bending angle of 90°.

8. The fan-out structure according to claim 7, wherein:
the insulating layer is formed on the first metal layer, and the second metal layer is formed on the insulating layer; or
the insulating layer is formed on the second metal layer, and the first metal layer is formed on the insulating layer.

9. The fan-out structure according to claim 7, wherein the first fan-out lines and the second fan-out lines are made of a same material.

10. An electronic device, comprising:
a substrate; and
a fan-out structure provided on the substrate, wherein the fan-out structure includes:
a plurality of first fan-out lines provided on a first metal layer; and
a plurality of second fan-out lines provided on a second metal layer, an insulating layer being disposed between the second metal layer and the first metal layer,
wherein vertical projections of the first fan-out lines on the second metal layer are alternately arranged with the second fan-out lines, and the vertical projections partially overlap with adjacent second fan-out lines.

11. The electronic device according to claim 10, wherein:
the insulating layer is formed on the first metal layer, and the second metal layer is formed on the insulating layer; or
the insulating layer is formed on the second metal layer, and the first metal layer is formed on the insulating layer.

12. The electronic device according to claim 10, wherein the first fan-out lines and the second fan-out lines are made of a same material.

13. The electronic device according to claim 10, wherein the electronic device is a liquid crystal display panel.

14. The electronic device according to claim 10, wherein each of the first fan-out lines and the second fan-out lines has a fan-out portion and a regulating portion connected to each other, the fan-out portion being straight wiring, and the regulating portion being curved wiring in a reciprocating manner with a bending angle of 90°; and
wherein a vertical projection of the regulating portion of each first fan-out line on the second metal layer partially overlaps with the regulating portion of a corresponding second fan-out line.

15. The electronic device according to claim 14, wherein:
the insulating layer is formed on the first metal layer, and the second metal layer is formed on the insulating layer; or
the insulating layer is formed on the second metal layer, and the first metal layer is formed on the insulating layer.

16. The electronic device according to claim 14, wherein the first fan-out lines and the second fan-out lines are made of a same material.

17. The electronic device according to claim 14, wherein the electronic device is a liquid crystal display panel.
